(19) United States
(12) Patent Application Publication
(10) Pub. No.: US 2025/0392258 A1
(43) Pub. Date: Dec. 25, 2025

(54) ASSISTED MILLIMETER WAVE GILBERT MIXER WITH A NEGATIVE TRANSCONDUCTANCE CELL

(71) Applicant: Apple Inc., Cupertino, CA (US)

(72) Inventor: Milad DARVISHI, San Diego, CA (US)

(21) Appl. No.: 19/097,822

(22) Filed: Apr. 1, 2025

Related U.S. Application Data
(60) Provisional application No. 63/663,065, filed on Jun. 21, 2024.

(51) Int. Cl. H03D 7/14

(52) U.S. Cl. CPC H03D 7/1466; H03D 7/1441; H03D 2200/0019

(57) ABSTRACT

A mixer may include a negative resistor, a transformer, a switching stage, and an input stage. The input stage may receive a radio frequency signal and output a current corresponding to a voltage of the radio frequency signal. The switching stage may switch based on a local oscillation signal. The mixer may be a down-conversion mixer that converts high-frequency millimeter-wave signals to an intermediate frequency.

### CROSS-REFERENCE TO RELATED APPLICATION(S)

This application claims the benefit of U.S. Provisional Application Ser. No. 63/663,065, entitled “ASSISTED MMW GILBERT-MIXER WITH A NEGATIVE GM-CELL,” and filed on Jun. 21, 2024, the disclosure of which is expressly incorporated by reference herein in its entirety.

### TECHNICAL FIELD

The present description relates generally to a mixer with a negative resistor. In some examples, the mixer may be a frequency conversion mixer.

### BACKGROUND

Frequency conversion mixers play a role in converting high-frequency millimeter-wave signals to a more manageable intermediate frequency, which may enable signal processing in wireless and other applications.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an example circuit diagram of a frequency conversion mixer.

FIG. 2A illustrates an example frequency conversion mixer that does not include a negative resistor.

FIG. 2B illustrates an example simplified circuit diagram of a frequency conversion mixer that does not include negative resistor.

FIG. 2C illustrates an example graph of qualitative variation of the different gains within the frequency conversion mixer of FIG. 2B.

FIG. 3 illustrates an example simplified circuit diagram of a frequency conversion mixer of FIG. 1 that includes a negative resistor.

FIG. 4 illustrates an example diagram of the common mode behavior of frequency conversion mixer.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

Frequency conversion mixers, such as millimeter-wave mixers may play a role in converting high-frequency signals to a more manageable intermediate frequency, enabling efficient signal processing in wireless and other applications. In some examples, such frequency conversion mixers may be millimeter-wave mixers. The disclosed subject matter may help with achieving signal to noise distortion ration (SNDR) and gain requirements for a frequency or frequency range within frequency range 2 (FR2) (e.g., 24 gigahertz (GHz) to 53 GHZ). In some examples, a mixer may be communicatively coupled with a fixed matching network. In an example, a millimeter-wave mixer may operate in the range of 37 GHz to 48 GHz. A challenge may be to maintain different parameters, such as gain, noise, or linearity, for such wide bandwidths. The disclosed subject matter may provide for efficiencies in operating millimeter-wave by using a negative resistor, which may use p-channel metal-oxide-semiconductors (PMOS). In an example, the down-conversion mixer may include an input stage configured to receive a radio frequency signal and output a current corresponding to a voltage of a radio frequency (RF) signal; a negative resistor, a transformer between the input stage and the negative resistor, and a switching stage configured to switch based on a local oscillation signal. The switching stage may be located between the negative resistor and an output of an intermediate frequency signal. The down-conversion mixer may be implemented in a mid-band or high-band of a receiver path.

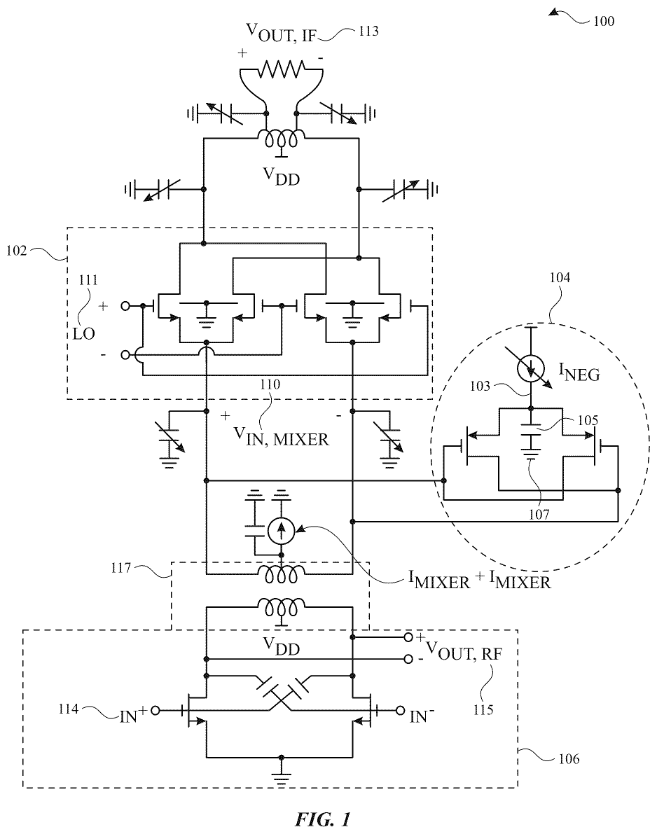

FIG. 1 illustrates an example circuit diagram of a millimeter-wave mixer 100 (e.g., Gilbert cell mixer) that includes a negative resistor 104 (e.g., produces a negative transconductance, −gₘ). Not all the depicted components may be used in all implementations, however, and one or more implementations may include additional or different components than those shown in the figure. Variations in the arrangement and type of the components may be made without departing from the scope of the claims as set forth herein. Additional components, different components, or fewer components may be provided.

Mixer 100 may have a single input and two outputs with its impacts further considered herein. Mixer 100 may include switching stage 102. Switching stage 102 may switch based on a local oscillation signal from local oscillator (LO) input 111 to generate an intermediate frequency (IF) signal with V_{out,IF} 113. An IF signal may be within a range from about 10 GHz to about 20 GHz in an example implementation. In another implementation, an IF signal may be within a range from about 10.5 GHz to about 12.7 GHZ. These ranges may be applicable in a circuit design that has a matching network (e.g., an impedance transformer).

Negative resistor 104 may be positioned between transformer 117 and the input of switching stage 102. It is contemplated herein that n-channel metal-oxide-semiconductor (NMOS) or p-channel metal-oxide-semiconductor (PMOS) may be implemented. PMOS may be selected, as shown, as it can be direct current (DC)-coupled with the switching stage 102 and may eliminate the use of alternating current (AC)-coupling capacitors that may be lossy at millimeter-wave frequencies. Negative resistor 104 may include capacitor 105 as shown. Capacitor 105 is positioned between net 103 (e.g., node) and ground 107. Negative resistor 104 may be designed with capacitor 105 with a capacitance associated with a frequency range. Capacitor 105 may have large enough capacitance to make sure at an RF frequency that net 103 is short (e.g., closed) at an RF frequency. For example, capacitor 105 should have a large enough capacitance to enable net 103 to be short between 37 GHz to 48 GHz. It is contemplated that there may be other negative resistor configurations.

Input stage 106 may include Vᵢₙ 114 and V_{out,RF} 115. Vᵢₙ 114 may be associated with a cross coupled pair, as shown. V_{out,RF} 115 may be connected with an apparatus, such as a power detector used for jammer detection or automatic gain control (AGC).

Generally, in beam-forming receivers, there is an attempt to maximize both the gain of the input stage 106 (V_{out,RF} 115/Vᵢₙ 114) and mixer (V_{out,IF} 113/V_{in,mixer} 110) for signal to noise distortion ratio (SNDR) performance in millimeter-wave frequencies, where gain may be scarce. As disclosed in more detail herein, there may be a conflicting requirement for the turn-ratio of the inter-stage transformer 117, for example, the impedance level at the output of the input stage may be an order of magnitude different from that of the input impedance of the mixer. Thus, if there is not a negative resistor 104, it may be difficult to design a low loss matching network.

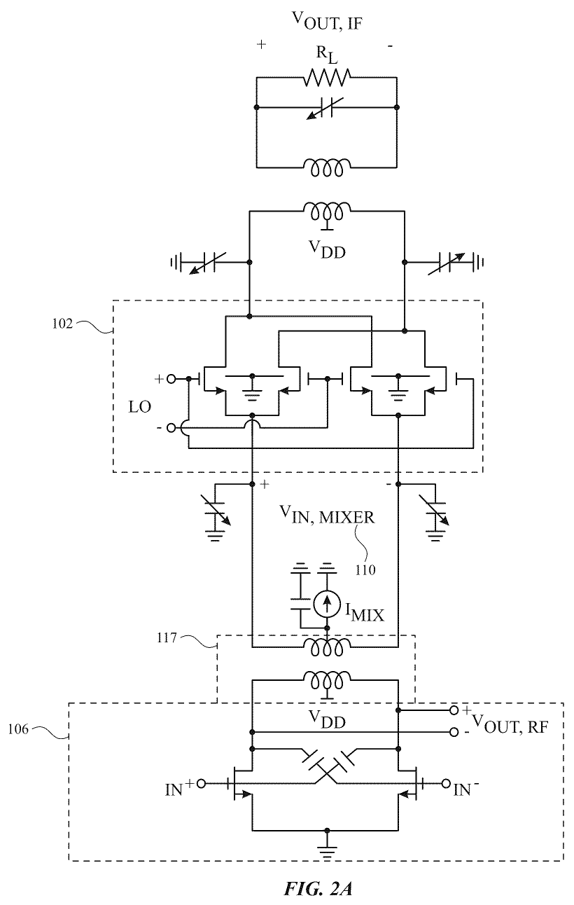

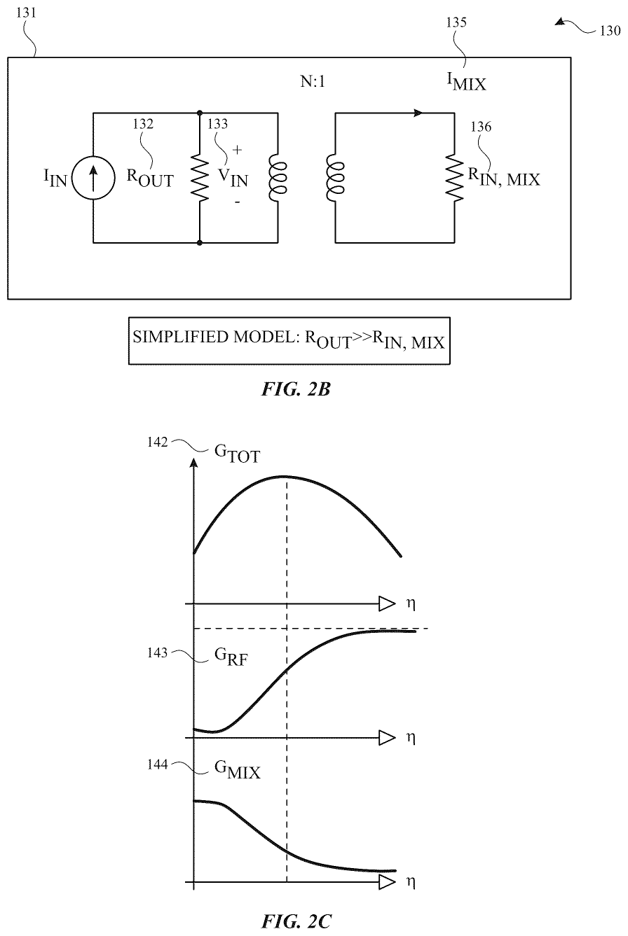

FIG. 2A illustrates an example millimeter-wave mixer that does not include a negative resistor. FIG. 2B illustrates an example simplified circuit diagram of a millimeter-wave mixer that does not include negative resistor 104. This simplified model 130 simplifies the input stage 106, transformer 117, and switching stage 102, without including negative resistor 104 (e.g., FIG. 2A). The gains may be described generally according to the following equations:

G_{RF} 143=Vᵢₙ 133/Iᵢₙ 131∝to the gain of the input-section. (RF gain)

Gₘᵢₓ 144=Iₘᵢₓ 135/Vᵢₙ 133∝to the voltage-gain of the mixer

Gₜₒₜ 142=Iₘᵢₓ 135/Iᵢₙ 131∝to the gain of the total gain

G_{RF} 143, Gₘᵢₓ 144 and Gₜₒₜ 142 in the context of FIG. 2B may be further described in the equations below.

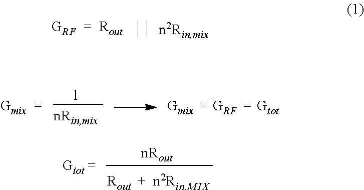

In addition, FIG. 2C illustrates an example graph of qualitative variation of the different gains within the mixer of FIG. 2B. As can be observed by FIG. 2C and the disclosed relationships of gain, there may be a tradeoff between G_{RF} 143 and Gₘᵢₓ 144 when n increases. As shown for equation set (1), when n increases Gₘᵢₓ 144 decreases and G_{RF} 143 increases which eventually leads to a decrease in Gₜₒₜ 142. With consideration of the simplified model of FIG. 2B, Rout 132 is significantly larger than Rin, mix 136, which makes an impedance match difficult and may lead to large transformer loss (gain) and degraded bandwidth (BW). The disclosed down-conversion mixer with negative resistor 104 may address some of the disclosed issues.

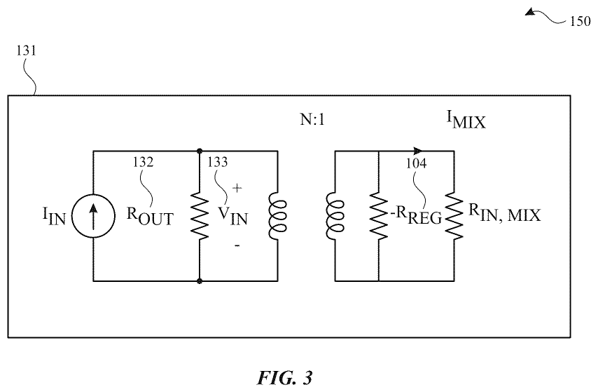

FIG. 3 illustrates an example simplified circuit diagram 150 of mixer 100 of FIG. 1 that includes negative resistor 104. G_{RF}, Gₘᵢₓ, and Gₜₒₜ in the context of FIG. 3 may be further described in the equations below.

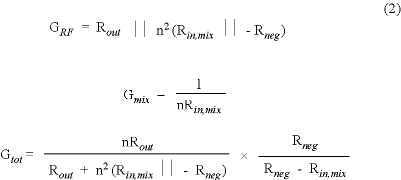

With reference to FIG. 3, by effectively increasing the resistance by adding negative resistor 104, less transformation-ratio (n) is required as shown in equation set (2). Also, because n is smaller relative to n of equation set (1), a larger Gₘᵢₓ is achievable at the same time. Furthermore, the total gain of the mixer may be increased as well. Negative resistor 104 increases the impedance seen by the switching stage 102, and reduces the noise and linearity contribution of switching stage 102. Testing has shown that negative resistor 104 improves the total noise performance with a given n, even if it adds its own noise and nonlinearity. The addition of negative resistor 104, adds a new variable in the aforementioned equations, which allows for the ratio of the transformer to be manipulated in a way to increase gain near simultaneously for the input stage 106 and mixer without increased power consumption (e.g., significantly less power) when compared to similar millimeter-wave mixers.

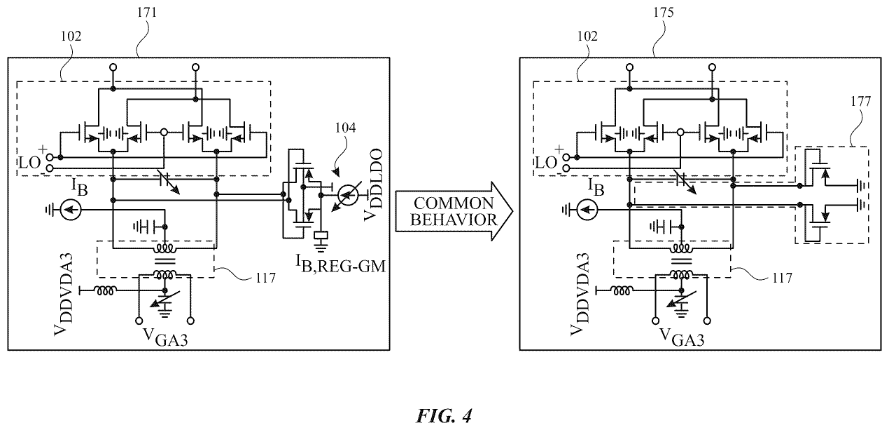

FIG. 4 illustrates an example diagram of the common mode behavior of negative resistor 104 (also referred herein as negative-gm). Negative resistor 104 as implemented with gilbert mixer as shown in diagram 171 may have the common mode behavior as a diode-connected device 177, as shown in diagram 175, and lowers the common-mode impedance. In addition, this configuration may be operated at significantly less power with similar noise than other similar millimeter-wave mixers.

In many of the FR2 millimeter-wave related receiver chains (e.g., to detect blockers and do AGC), a wide-band power-detector (e.g., wideband received signal strength indicator-WRSSI) may be connected at the input of the mixer. Some power detectors generally cannot distinguish between common-mode/differential or desired/undesired signals. Thus, by design, there is a need to reduce any undesirable signal sensed by WRSSI. The common-mode 2LO leakage is one of the largest of such signals. The disclosed subject matter leads to lowering this 2LO leakage by selectively lowering the common-mode signal seen by the mixer's switching-quad at their source node.

Methods, systems, or apparatuses, among other things, as described herein may provide for a mixer (e.g., millimeter-wave down-conversion mixer) that may include a negative gm cell. A method, system, or apparatus may include an input stage configured to receive a radio frequency signal and to output a current corresponding to a voltage of the RF signal; a negative resistor; a transformer between the input stage and the negative resistor; and a switching stage configured to switch based on a local oscillation signal. The RF signal may have a frequency ranging from about 37 GHz to about 43 GHz. The RF signal may have a frequency ranging from about 47 GHz to about 48 GHz. The input stage may include a cross coupled pair, wherein the cross-coupled pair comprises one or more capacitors. The cross-coupled pair may act as a negative-resistor in the differential resistor to increase the impedance level and perform as a positive resistor in common-mode to reduce the common-mode resistor. A differential resistor is an electronic component that provides a varying resistance in response to changes in voltage or current. A method, system, or apparatus may include a transformer connected with a first node and a second node; a first transistor having a first gate connected with the first node; a second transistor having a second gate connected with the second node; a capacitor connected with a first source of the first transistor and the capacitor connected with a second source of the second transistor; a third transistor having a gate receiving a positive oscillation signal and a source connected with the first node; and a fourth transistor having a gate receiving a negative oscillation signal and a source connected with the second node. The disclosed negative resistor may be implemented in circuits generally designed with FIG. 1 or FIG. 2A in consideration. The negative resistor may include a p-channel metal-oxide-semiconductor (PMOS) transistor or n-channel metal-oxide-semiconductor (NMOS) transistor. The negative resistor may include a capacitor between a node and ground. The negative resistor may be coupled with the switching stage. All combinations (including the removal or addition of components) in this paragraph are contemplated in a manner that is consistent with the other portions of the detailed description.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, or at least one of any combination of the items, or at least one of each of the items. By way of example, the phrases “at least one of A, B, and C” or “at least one of A, B, or C” each refer to only A, only B, or only C; any combination of A, B, and C; or at least one of each of A, B, and C. The term “or” is generally used inclusively herein.

The predicate words “configured to”, “operable to”, and “programmed to” do not imply any particular tangible or intangible modification of a subject, but, rather, are intended to be used interchangeably. In one or more implementations, a processor configured to monitor and control an operation, or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some implementations, one or more implementations, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “example” is used herein to mean “serving as an example, instance, or illustration”. Any embodiment described herein as “example” or as an “example” is not necessarily to be construed as preferred or advantageous over other implementations. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A down-conversion mixer, comprising:
an input stage configured to:
receive a radio frequency (RF) signal, and
output a current corresponding to a voltage of the RF signal;
a negative resistor;
a transformer between the input stage and the negative resistor; and
a switching stage configured to switch based on a local oscillation signal.

2. The down-conversion mixer of claim 1, wherein the RF signal has a frequency in a range from 24 gigahertz (GHz) to 36 GHz.

3. The down-conversion mixer of claim 1, wherein the RF signal has a frequency in a range of 36 gigahertz (GHz) to 53 GHZ.

4. The down-conversion mixer of claim 1, wherein the input stage comprises a cross-coupled pair, wherein the cross-coupled pair comprises one or more capacitors.

5. The down-conversion mixer of claim 4, wherein the cross-coupled pair is configured to operate as a negative-resistor in a differential resistor to increase an impedance level.

6. The down-conversion mixer of claim 4, wherein the cross-coupled pair is configured to operate as a positive resistor in common-mode to reduce a common-mode resistor.

7. The down-conversion mixer of claim 1, wherein the negative resistor comprises a p-channel metal-oxide-semiconductor (PMOS) transistor.

8. The down-conversion mixer of claim 1, wherein the negative resistor comprises a n-channel metal-oxide-semiconductor (NMOS) transistor.

9. The down-conversion mixer of claim 1, wherein the negative resistor comprises a capacitor between a node and ground.

10. The down-conversion mixer of claim 1, wherein the negative resistor is coupled with the switching stage.

11. A down-conversion mixer comprising:
a transformer connected with a first node and a second node;
a first transistor comprising a first gate connected with the first node;
a second transistor comprising a second gate connected with the second node;
a capacitor connected with a first source of the first transistor and a second source of the second transistor;
a third transistor comprising:
a gate configured to receive a positive oscillation signal, and
a third source connected with the first node; and
a fourth transistor comprising:
a gate configured to a negative oscillation signal, and
a fourth source connected with the second node.

12. The down-conversion mixer of claim 11, wherein the capacitor is connected with ground.

13. The down-conversion mixer of claim 11, wherein the second transistor comprises a second drain, wherein the second drain is connected with the first node.

14. The down-conversion mixer of claim 11, wherein the first transistor comprises a first drain, wherein the first drain is connected with the second node.

15. The down-conversion mixer of claim 11, wherein the transformer is connected with a third node, wherein the third node is connected with a fifth drain of a fifth transistor.

16. The down-conversion mixer of claim 15, wherein the transformer is connected with a fourth node, wherein the fourth node is connected with a sixth drain of a sixth transistor.

17. The down-conversion mixer of claim 11, wherein the transformer is connected with a third node, wherein the third node is connected with a fifth drain of a fifth transistor, wherein the fifth transistor comprises a fifth source, wherein the fifth source is connected with ground.

18. The down-conversion mixer of claim 17, wherein the transformer is connected with a fourth node, wherein the fourth node is connected with a sixth drain of a sixth transistor, wherein the sixth transistor comprises a sixth source, wherein the sixth source is connected with ground.

19. The down-conversion mixer of claim 11, wherein the transformer is connected with a third node, wherein the third node is connected with a second capacitor.

20. The down-conversion mixer of claim 19, wherein the transformer is connected with a fourth node, wherein the fourth node is connected with a third capacitor.
